(19) United States
(12) Patent Application Publication
(10) Pub. No.: US 2008/0236656 A1
(43) Pub. Date: Oct. 2, 2008

(54) Embedded transformable nanofilaments in multilayer crystalline space for photovoltaic cells and method of fabrication

(75) Inventor: Neal Solomon, Oakland, CA (US)

Correspondence Address: Neal Solomon, PO Box 21297, Oakland, CA, 94620, US

(73) Assignee: Solomon Research LLC, Oakland, CA (US)

(21) Appl. No.: 11/985,072

(22) Filed: Nov. 13, 2007

Related U.S. Application Data
(60) Provisional application No. 60/865,605, filed on Nov. 13, 2006.

(51) Int. Cl. H01L 31/04; H02J 7/00; H01L 31/18

(52) U.S. Cl. 136/252; 320/101; 438/57

(57) ABSTRACT

The invention pertains to the use of nanotechnology in photovoltaic (PV) cells. The apparatus is comprised of a multilayer crystalline media within which are embedded adaptive nanofilaments. The system efficiently emulates the natural process of photosynthesis and includes an efficient storage capability. A method of fabrication of the components and the apparatus is also disclosed.

### CROSS-REFERENCES TO RELATED APPLICATIONS

The present application claims the benefit of priority under 35 U.S.C. § 119 from U.S. Provisional Patent Application Ser. No. 60/865,605, filed on Nov. 13, 2006, the disclosure of which is hereby incorporated by reference in its entirety for all purposes.

### FIELD OF THE INVENTION

The present invention involves photovoltaic (PV) cells. A new PV apparatus is described as well as a method of manufacture.

### BACKGROUND OF THE INVENTION

Much research has been done in developing new photovoltaic (PV) cell technology because of the need to improve clean energy efficiency and productivity and to remove dependence on foreign oil.

A PV works in several phases by (a) capturing sunlight, (b) separating the positive and negative charges, (c) combining the charges and filtering off useful energy and (d) distributing the energy to storage. The main organizational model for PV technology is the process of photosynthesis. In order to improve PV technology we need to understand photosynthesis, thus the following description provides a synopsis.

Three main nanostructures are involved in biological photosynthesis: (i) an antenna, (ii) a reaction center and (iii) a membrane charge management structure. The antenna has light collecting areas called the “light harvesting complex.” The light harvesting complex uses rings of molecules that exchange energy to the reaction center. In the reaction center an electron is separated from its opposite charge (called a “hole”). The electron is removed from the hole by a nanostructure comprised of an organic compound (quinine) and an iron atom. The transferred charge is used to create a sloping structure for hydrogen ions across the casing. In photosynthetic mechanisms, this charge recombination creates the chemical ATP, which is essential in storing energy for cellular processes.

PV technology seeks to emulate photosynthetic processes to create artificial photosynthesis.

In traditional PV cells, a crystalline semiconductor absorbs sunlight and converts the light into heat energy; the excited electrons are siphoned off using a grid of filaments and stored outside of the solar cells. The main drawbacks of this traditional PV technology are its limited efficiency and high cost relative to other energy production sources. The challenge is to develop a system to mass-produce low-cost, highly efficient PVs.

Nanosolar has patented a range of inventions on methods for self-assembly of nanoparticles and process technology for PV mass-production. These technologies marginally increase the efficiency while also reducing the weight, size and cost of producing the main semiconductors in the PVs. In addition, Energy Innovations has developed a system of pivoting micro-mirrors that amplify solar energy.

In addition to these PV technologies, Charles Lieber at Harvard University has developed “polymer bubble” nanowire films that stack layers of two dimensional nanowire arrays. Nanowires may be implemented in PV devices to increase efficiency of energy collection and distribution.

These inventions seek to increase efficiencies and lower the costs of producing PV cells, though they do not use intelligent systems or collective behaviors to achieve these efficiencies. Since intelligent systems are adaptive, they increase efficient use of resources by adjusting to the changing environmental conditions such as solar energy variability.

Further challenges are to improve the processes of separating positive and negative charges, of reintegrating and filtrating useful Coulombic energy, and of efficiently distributing the energy. While the distribution part of the process may be improved by increasing insulation (to reduce leakage) and by reducing the distance from energy production structures to storage, the real challenge lies in designing efficient production architectures. In this area, nanotechnology models are very useful.

### SUMMARY OF THE INVENTION

The invention describes a photovoltaic cell architecture that features four main layers. The layers are sandwiched on thin film materials infused with varying, and adjustable, nanofilaments. The four layers have sensors that communicate functionality of each layer to the other layers to optimize performance of energy collection and distribution. The center two layers adjust position, while the second layer adjusts configuration, in order to maximize efficiency of energy collection and distribution.

The PV device is fabricated by constructing each layer and combining the layers into an integrated system.

The system emulates natural photosynthetic processes.

### Advantages of the System

The system increases PV cell performance by maximizing light collection and energy conversion and distribution.

The system specifies a set of efficient fabrication techniques to manufacture the PV system at low cost.

The PV architecture of the invention is scalable from micro size to large sheets for multiple applications from electronics to industry.

### DESCRIPTION OF THE INVENTION

The present invention has multiple layers, like strata of ultra-thin film that are sandwiched to one another. While the materials vary, these hybrid nanostructures consist of titanium dioxide (for the nanofilaments) and copper indium gallium diselenide (CIGS) or other exotic crystalline materials for the semiconductor stratum.

On the first layer of the PV apparatus, organic circular nanostructures (made of dye) appear in random patterns like raindrops. This layer absorbs the sunlight and transfers the light energy to the second layer. The second and third layers are integrated and consist of charge decoupling and charge recoupling structures. The two connected middle layers link the bottom (fourth) processing layer and the top (first) collection layer. After the second layer decouples electrons from the negatively-charged hole with a nanofilament system, it feeds the electrons to the connected third layer. The third layer recouples the useful Coulomb energy of the electrons and feeds the electrons to the fourth layer for distribution and storage. These layers represent the four main phases of the PV process.

As the apparatus becomes excited with increasing heat, the filaments in the gradient filament grid structure changes its organizational position to decrease the distance between filaments. This cluster reconfiguration process increases the efficiency of the collection and filtration of electrons. Because the second and third layers are connected, and sandwiched between the first and fourth layers, the reduced distance between the main structures for collection, transformation and distribution of electrons limits leakage and thereby increases efficiency.

In the second layer, the nanofilaments are arranged as “tributaries” to maximize electron collection transport. In this layer, the nanofilaments, when stimulated by increased heat, reposition and broaden their configuration to boost efficiency. The main source of stimulus for the nanofilaments is heat generated by increased light absorption, although they are also stimulated by nanosensors integrated into the system. The system modulates optimum electron flow by using the transformable embedded nanofilaments. The automatic transformation process occurs over the period of a day in which the sun's changing position increases the heat at peak mid-day.

The electrons from the second layer are sent to the third layer for collection of useful Coulomb energy and then distributed to storage. Since the second and third layers are integrated, these sequential processes are efficient.

In one embodiment of the system, the nanofilaments are organized into triad structures that penetrate the second layer in such a way that the endpoints integrate with the third layer. This coupled architecture, when combined with the transformable tributary system, provides a major increase in solar energy productive efficiency.

In the fourth, or bottom, layer of the multi-layer integrated PC device, a preferred embodiment is comprised of a mirror that reflects and amplifies heat energy back to the coupled second and third layers.

The sensors embodied in each layer exchange information to optimize system performance. In particular, the sensors at layers one and four provide light and heat data to adjust layers two and three for optimum collection and transmission of energy.

The modular nanofilament system is used with a range of PV technologies but requires manufacturing processes to create ultra-thin nanofilaments, nanosensors that activate these and sandwiching techniques to integrate these main layers into the four-layer assembly. The structures are built using semiconductor technologies, thereby keeping their production costs low when manufactured in mass quantities. This novel system for PV architecture and production is also able to integrate well into other nanotechnologies for solar power.

A “thin film PV nanofilament fabricator,” which resembles a large photo printer, constructs the four layer nano PV in phases. Each of the four PV layers is constructed separately. In one embodiment, the thin film is constructed of copper indium gallium diselenide (CIGS) and the nanofilaments are constructed from titanium dioxide. The film is fed in to the feeder device of the fabricator, on which the nanofilaments are distributed in different configurations as specified above.

The nanofilaments are distributed on layers 1, 2 and 3 by enabling the fabricator in three main modes. For layer 1, the nanofilaments are randomly distributed on hydrophobic polymer. For layer 2, the nanofilaments are distributed at an angle from the center of the film. For layer 3, the nanofilaments are distributed in parallel arrays at 90 degrees. The films are heated for manufacture. The thin film may be manufactured in varying sizes, including large (80 by 120 inch) sheets as well as micron-scale device sizes. In effect, each layer is “printed out.”

The film layers are sandwiched together in a separate process. The second and third layers are coupled first. This film combination is then combined with layer 1 and this assembly is attached to layer 4. The 4-layer assembly is attached to a frame with connectors at side seams.

Nanofilaments connect the layers at the side seams. Nanofilaments connect layer 4 to energy storage capability. Nanosensors are attached to each layer at specific intervals and are connected by nanofilaments.

In one embodiment, the architecture of the present system is applied to micron to micro scale devices for electronic device power applications.

Reference to the remaining portions of the specification, including the drawings and claims, will realize other features and advantages of the present invention. Further features and advantages of the present invention, as well as the structure and operation of various embodiments of the present invention, are described in detail below with respect to accompanying drawings.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference for all purposes in their entirety.

### DESCRIPTION OF THE DRAWINGS

FIG. 1 is a diagram illustrating a cross section of layers of a photovoltaic (PV) cell device.

FIG. 2 is a diagram showing the operation of the PV cell device.

FIG. 3 is a diagram showing the configuration of the first layer of the PV cell device.

FIG. 4 is a diagram showing the operation between layers three and four of the PV cell device.

FIG. 5 is a diagram showing the configuration of the second layer of the PV cell device.

FIG. 6 is a diagram showing the configuration of the third layer of the PV cell device.

FIG. 7 is a diagram showing the connection between the second and third layers of the PV cell device.

FIG. 8 is a diagram showing the process of interaction between the second and third layers of the PV cell device as they adapt their configuration under specific conditions.

FIG. 9 is a diagram showing the nanosensors in a PV cell device.

### DETAILED DESCRIPTION OF THE DRAWINGS

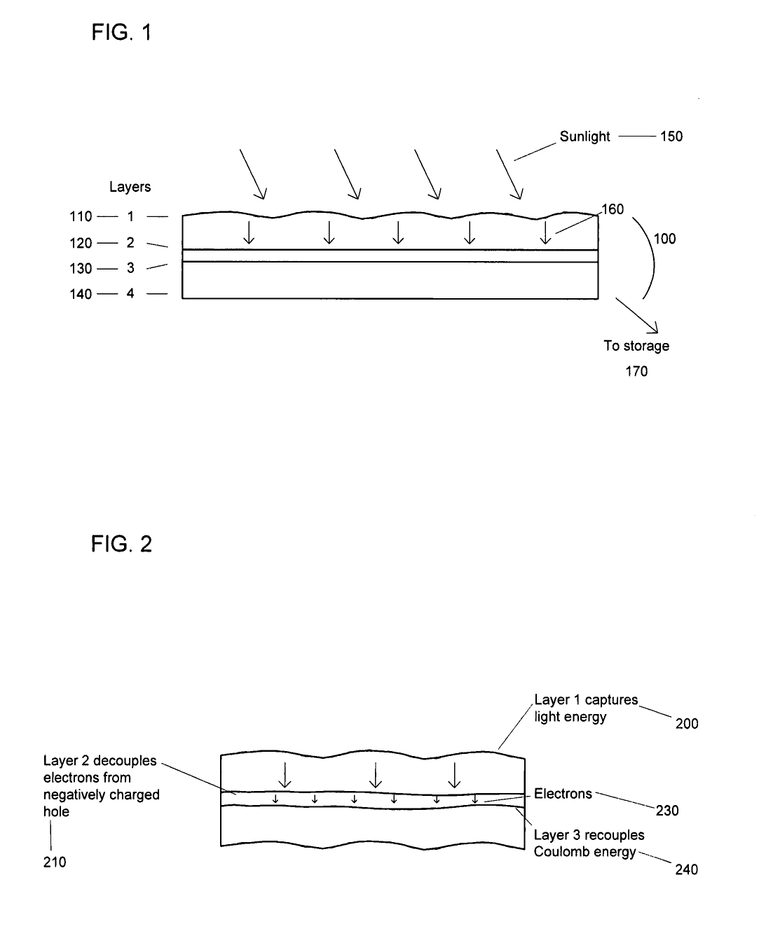

FIG. 1 shows a cross section of the photovoltaic (PV) cell device. Sunlight (150) strikes the first layer (110) and penetrates (160) the device to reach the second layer (120). The second layer converts the light to electricity at the sandwich of layers two and three (130). Layer four is shown (140) and in one embodiment contains a mirror to enhance the heat energy at layer 3. The converted energy is then siphoned off to storage (170).

FIG. 2 shows the capturing of light energy at layer one (200), the decoupling of electrons from a negatively charged hole (210) at layer two, the conversion of the electrons (230) between layers two and three and the recoupling of Coulomb energy (240) at layer three.

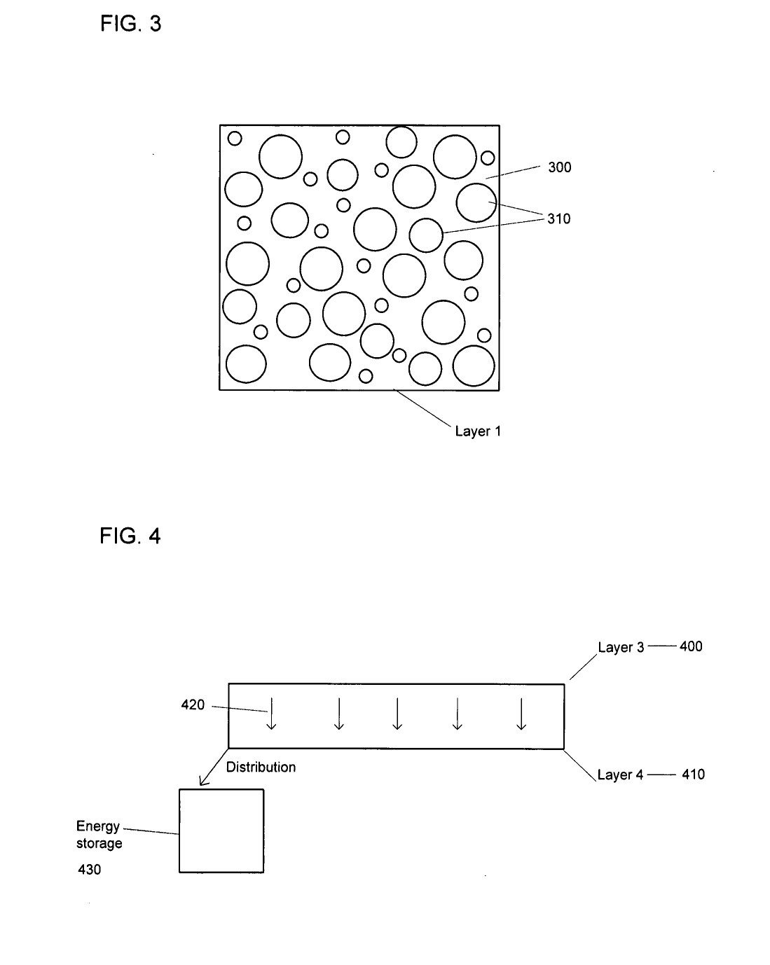

FIG. 3 shows the random configuration of nanofilaments (310) on the substrate (300) of layer one of the device.

FIG. 4 shows the connection between layers three and four of the device. Energy is converted from light energy to heat energy (420) and then to electrons at these layers (400 and 410) and is distributed for energy storage (430).

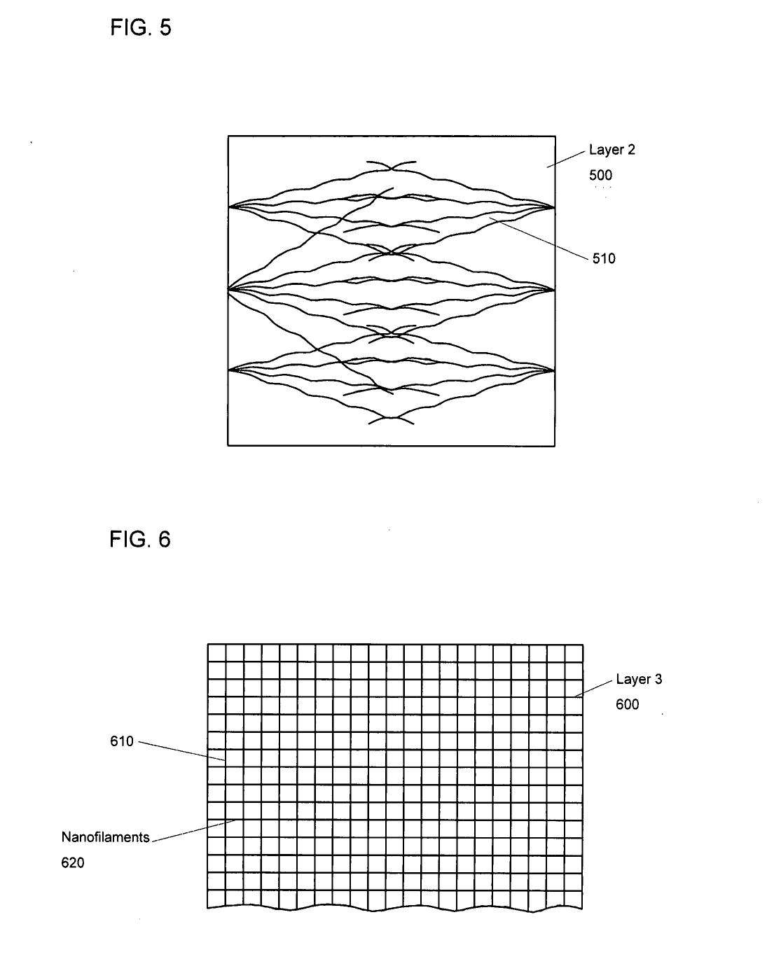

FIG. 5 shows the nanofilaments (510) distributed on layer two (500). The nanofilaments on this layer change their configuration as the heat energy excites their filaments. Specifically, the tributary configuration narrows and widens. The nanofilaments narrow when excited by heat energy. This model optimizes the collection of electrons. FIG. 6 shows the nanofilaments (610) distributed on layer three (600). The nanofilaments are laid down at 90 degree angles in a grid configuration. The stacking of the nanofilaments occurs by alternating aligned grids comprised of nanowire arrays. A “polymer bubble” of nanowire films is used. This configuration maximizes the efficiency of the system.

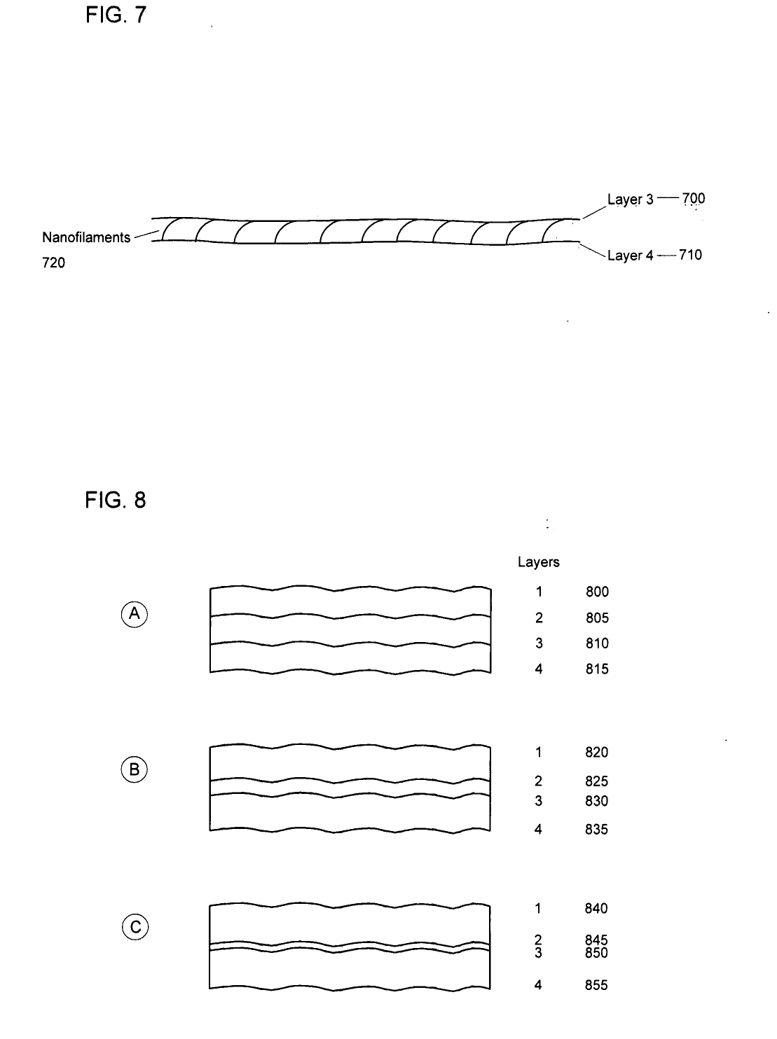

FIG. 7 shows the configuration of the assembly connecting layers three and four. Nanofilaments (720) connect layers three (700) and four (710).

This assembly between layers two and three is shown to oscillate as described in FIG. 8. In FIG. 8, three phases are depicted for oscillation of the assembly between layers two and three. In phase A, layers two (805) and three (810) are separated by a substantial gap. At phase B, the two layers (825 and 830) are represented closer together in order to maximize the efficiency of the collection of energy at peak times. At phase C, the two layers (845 and 850) are at their closest distance in order to optimize this process of energy conversion and collection.

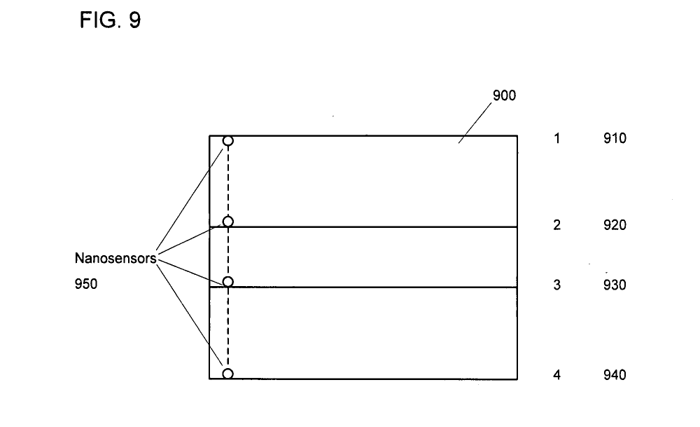

FIG. 9 shows the nanosensors (950) connected to specific layers (910, 920, 930 and 940). The use of nanosensors is useful to exchange information from each layer about its state to the other layers in order to perform a specific action. The nanosensors are connected by nanofilaments.

What is claimed is:

1. A system for organizing a photovoltaic cell, comprising:
A first layer for absorbing light rays;
A second layer for receiving light and converting the light to electrons and for separating the electrons and the hole;
A third layer for combining the electrons and hole into Coulomb energy; and
A fourth layer for distributing the electrons to energy storage device.

2. A system of claim 1 wherein the first layer has nanofilaments distributed randomly in a circular pattern on its surface to efficiently collect light.

3. A system of claim 1 wherein the second layer has nanofilaments distributed in a tributary configuration on its surface to efficiently process the electrons collected; and
Wherein the second layer filaments adjust their configuration to widen when heated and narrow when cooled so as to maximize the collection of the light energy and conversion of the light to electrons.

4. A system of claim 1 wherein the third layer has nanofilaments distributed by using a polymer bubble in which a grid configuration is organized at ninety degrees in order to optimize the processing of the electrons.

5. A system of claim 1 wherein the fourth layer has a mirror finish to amplify the heat generated in the first three layers as it collects light and converts it to electrons; and
wherein the collected electrons are transferred to an energy storage device.

6. A system of claim 1 wherein the second and third layers are coupled and interactive;
Wherein the second and third layers move closer together to a limit as the temperature of the system increases and move further apart to a standard position as the temperature of the system decreases to an average or below average level.

7. A system of fabricating a photovoltaic cell, comprising:
Generating specific layers of material from copper indium gallium diselenide (CIGS);
Combining the CIGS to nanofilaments comprised of titanium dioxide;
Distributing the nanofilaments on specific layers of the CIGS;
Combining nano-sensors to the specific layers at specific points in a grid;
Managing the coordination of the nano-sensors in order to allow the multiple layers to be able to communicate their conditions to other layers;
Sandwiching layers two and three together using a frame mechanism that allow the two layers to oscillate;
Sandwiching layers one and four together after combining layers two and three; and
Connecting the PV apparatus to a connector that fits into a storage device.
